(19) United States
(12) Patent Application Publication
(10) Pub. No.: US 2024/0204476 A1
(43) Pub. Date: Jun. 20, 2024

(54) OPTOELECTRONIC SEMICONDUCTOR COMPONENT

(71) Applicant: ams-OSRAM International GmbH, Regensburg (DE)

(72) Inventors: Josef Hirn, Schwandorf (DE); Martin Nömer, Donaustauf (DE); Hannes Walther, Regensburg (DE); Tilman Rügheimer, Regensburg (DE); Roland Hüttinger, Kaufering (DE); Elmar Baur, Regensburg (DE); Ralf Wombacher, Burglengenfeld (DE)

(73) Assignee: ams-OSRAM International GmbH, Regensburg (DE)

(21) Appl. No.: 18/555,787

(22) PCT Filed: Apr. 12, 2022
(86) PCT No.: PCT/EP2022/059738

§ 371 Date: Oct. 17, 2023

(30) Foreign Application Priority Data
Apr. 20, 2021 (DE) 102021109968.4

(51) Int. Cl. H01S 5/02315; H01S 5/02257

(52) U.S. Cl. CPC H01S 5/02315; H01S 5/02257

(57) ABSTRACT

Disclosed is an optoelectronic semiconductor component including at least one optoelectronic semiconductor chip in an interior of a housing; the housing has a base part and a top part, the base part is a ceramic support, the top part is made of one or more glass materials, a connection layer that is made of a solder glass is arranged between the base part and the top part, and the ceramic support includes a connection portion with a nickel-containing surface which is in direct contact with the solder glass.

### CROSS-REFERENCE TO RELATED APPLICATIONS

The present application is a national stage entry from International Application No. PCT/EP2022/059738, filed on Apr. 12, 2022, published as International Publication No. WO 2022/223370 A1 on Oct. 27, 2022, and claims priority to German Patent Application No. 10 2021 109 968.4, filed Apr. 20, 2021, the disclosures of all of which are hereby incorporated by reference in their entireties.

### FIELD OF THE INVENTION

An optoelectronic semiconductor device is specified.

### BACKGROUND OF THE INVENTION

For high-quality and sensitive microelectronics, hermetic housings are usually used to protect the electronic components from damaging environmental influences. Laser diodes, for example, but also other electronic and in particular optoelectronic components, are mounted in a hermetically sealed housing. Such a housing provides the connection, in particular also the electronic connection, of the internally arranged components to the external environment.

For example, ceramic housings are known in which a base plate, a frame mounted thereon and a cover mounted on the frame, which can also be transparent depending on the type of component mounted in the housing, are each connected to one another by means of metallic solder layers. For example, a gold-tin solder can be used. However, for such a solder connection, all surfaces to be connected must have a metallization in the connecting regions, and two of these metallizations must be coated with a gold-tin solder. Side-emitting devices usually have as a housing, for example, a base plate on which a metal cap is mounted by means of soldering or welding, in which a glass window is integrated. These known housing solutions are time-consuming and thus expensive in manufacture.

At least one object of certain embodiments is to provide an optoelectronic semiconductor device.

This object is achieved by a subject-matter according to the independent claim. Advantageous embodiments and developments of the subject-matter are characterized in the dependent claims, and are also disclosed by the following description and the drawings.

### SUMMARY OF THE INVENTION

According to at least one embodiment, an optoelectronic semiconductor device comprises at least one optoelectronic semiconductor chip in an interior space of a housing. In particular, the at least one optoelectronic semiconductor chip can be a semiconductor chip that can be sensitive to substances from the surrounding atmosphere, such as moisture and/or oxygen. For example, the at least one optoelectronic semiconductor chip can be a semiconductor laser diode. Although the following description focuses on an embodiment of the optoelectronic semiconductor chip as a semiconductor laser diode, other embodiments of semiconductor chips are alternatively possible, such as a superluminescent diode (SLED), a light emitting diode (LED), a photodiode, or another optoelectronic semiconductor chip. Although the following description focuses on an optoelectronic semiconductor device with one optoelectronic semiconductor chip, it is also possible for the optoelectronic semiconductor device to have a plurality of the same or different optoelectronic semiconductor chips and/or other electronic components in the housing.

Particularly preferably, the housing is hermetically sealed. The interior space of the housing can thus preferably be hermetically sealed from the environment by the housing. “Hermetically” or “hermetically sealed” can mean here and in the following in particular that damaging substances or other damaging influences from the environment cannot enter the interior space to such an extent that a damaging effect is caused thereby, for example, in the course of a usual expected or specified service life.

According to a further embodiment, the housing has a base part and a cover part. Between the base part and the cover part there is preferably a connecting layer by means of which the cover part is mounted, i.e. fastened, to the base part. The interior space of the housing is enclosed by the base part and the cover part and the connecting layer. In particular, at least the base part or the cover part or both can have a recess through which the interior space is formed when the base part and the cover part are joined together and mounted to each other by means of the connecting layer. Particularly preferably, the interior space can be hermetically sealed by the base part, the connecting layer and the cover part.

The at least one optoelectronic semiconductor chip is mounted on the base part and is preferably electrically connected. The direction of arrangement of the at least one optoelectronic semiconductor chip on the base part is also referred to as the vertical direction in the following. Directions perpendicular to the vertical direction, which can be parallel to a main extension plane of the base part and in particular a mounting surface of the base part, are hereinafter referred to as lateral directions.

For electrical contacting of the components arranged in the housing, such as the at least one optoelectronic semiconductor chip, the housing, particularly preferably the base part, has at least one electrical contact element. The at least one electrical contact element can, for example, comprise or be formed by one or more conductor tracks, one or more electrical feedthroughs (“vias”), one or more leadframes or leadframe parts, one or more electrode surfaces and combinations thereof on one or more surfaces of the base part and/or embedded in the base part. In particular, the housing can include a plurality of electrical contact elements. For example, the base part can have, as contact elements, at least two vias each connecting an electrode surface in the interior space to an electrode surface on an exterior surface of the base part facing away from the interior space.

According to a further embodiment, the base part is formed as a ceramic carrier. In other words, the base part can have a ceramic material, for example with or made of aluminum nitride, as the main component.

The ceramic carrier can preferably be a single-layer ceramic carrier or a multilayer ceramic carrier. A single-layer ceramic carrier can, for example, be plate-shaped and thus form a base plate. The single-layer ceramic carrier can be formed by a layer of a ceramic material, which can furthermore still have contact elements via which the at least one optoelectronic semiconductor chip in the interior space of the housing can be electrically contacted from the outside. A multilayer ceramic carrier can be formed from at least two or more layers of the same ceramic material or of different ceramic materials, which are applied to one another and sintered to form the base part. For example, one of the layers can form a base plate on which the at least one optoelectronic semiconductor chip is mounted, while at least one other layer is frame-shaped and laterally surrounds the at least one optoelectronic semiconductor chip. Accordingly, the base part can have a recess in which the at least one optoelectronic semiconductor chip is arranged.

Particularly preferably, the housing can be surface-mountable. The optoelectronic semiconductor component can thus particularly preferably be a surface-mountable component, i.e. a so-called SMD component (SMD: “surface-mounted device”), which can be mounted on a carrier such as a printed circuit board by soldering. Particularly preferably, the ceramic carrier can be surface-mountable.

According to a further embodiment, the cover part is formed of one or more glass materials. In other words, the cover part can be formed as a glass lid, that is, formed entirely of one or more glass materials. Particularly preferably, the cover part can comprise or be made of a borosilicate glass.

Preferably, the base part and the cover part have materials with similar coefficients of thermal expansion. For example, the base part, in particular the ceramic material of the base part, can have a first coefficient of thermal expansion C1 and the cover part, in particular the glass material(s) of the cover part, can have a second coefficient of thermal expansion C2, where |C1−C2|/<C1,C2>≤0.90 or |C1−C21 |/<C1,C2>≤0.95 or |C1−C2|/<C1,C2>≤0.99. Here, <C1,C2>denotes an average of C1 and C2.

Particularly preferably, the cover part can be completely light-transmitting. “Light-transmitting” in this context can mean at least translucent and preferably optically clear translucent, i.e. transparent. For example, the cover part can include an optical window arranged in a frame part. The frame part and the optical window can be made of the same glass material and, for example, fused together. Further, it can also be possible for the optical window to comprise a first glass material while the frame part comprises a second glass material different from the first glass material. Also in this case, the optical window can be fused to the frame part. Depending on the embodiment of the optoelectronic semiconductor device, the optical window can be arranged in a lateral direction adjacent to the optoelectronic semiconductor chip or in a vertical direction above the optoelectronic semiconductor chip.

Furthermore, the cover part can have a recess in which the optoelectronic semiconductor chip is at least partially arranged. The cover part can thus span the at least one optoelectronic semiconductor chip, for example, in a dome-like manner.

According to a further embodiment, the connecting layer comprises a glass solder and is particularly preferably made of a glass solder. By means of a glass solder, it can advantageously be possible to compensate for unevenness and other irregularities in a magnitude of up to 20 μm or even more on a joint surface. In comparison, a solder joint typically requires that unevenness and other irregularities be significantly smaller, such as in the range of 5 μm or less. Furthermore, the connecting layer formed by a glass solder for mounting the cover part on the base part can be directly adjacent to the cover part and in direct contact with the cover part. Thus, it is not necessary to provide an adhesion-promoting layer such as metallization, as would be necessary in the case of a solder joint, on the cover part.

According to a further embodiment, the base part, in particular the ceramic carrier, has a connecting region. The connecting region is the region of the base part and, in particular, of the ceramic carrier to which the connecting layer is applied. Particularly preferably, the base part and, in particular, the ceramic carrier has a nickel-containing surface in the connecting region, which is in direct contact with the connecting layer, i.e. in particular the glass solder. A particularly good adhesion of the glass solder can be achieved by a nickel-containing surface. For example, the nickel-containing surface can be formed by a nickel-containing layer. Particularly preferably, the nickel-containing layer can have a relative proportion of greater than or equal to 95 vol % nickel based on a total volume of the nickel-containing layer.

In accordance with the previously described embodiments and features, the optoelectronic semiconductor device described herein preferably features a ceramic carrier in the form of a single-layer ceramic or a multilayer ceramic as the base part. In particular, a multilayer ceramic design can enable the fabrication of miniature 3D interconnect solutions that provide extremely high density I/O interconnects while maintaining small form factors for both feedthroughs and PCB substrates. The ceramic material's high thermal conductivity and temperature resistance make it ideally suited for the application. In addition, the ceramic design enables solderable (SMD) components. In combination with the cover part as a glass window or with a glass window, this design also represents a particularly suitable housing for a laser emitter, for example. The glass solder, which can be reliably applied and fixed to the ceramic carrier by means of the nickel-containing surface, makes it possible to create a hermetically sealed connection between the base part and the cover part at low cost.

### BRIEF DESCRIPTION OF THE DRAWING

Further advantages, advantageous embodiments and further developments are revealed by the embodiments described below in connection with the figures.

FIG. 1 shows a schematic illustration of an optoelectronic semiconductor device according to an embodiment,

FIGS. 2A to 2F show schematic illustrations of a cover part according to further embodiments and

FIGS. 3A to 3C show schematic illustrations of an optoelectronic semiconductor device according to further embodiments.

### DETAILED DESCRIPTION

In the embodiments and figures, identical, similar or identically acting elements are provided in each case with the same reference numerals. The elements illustrated and their size ratios to one another should not be regarded as being to scale, but rather individual elements, such as for example layers, components, devices and regions, can have been made exaggeratedly large to illustrate them better and/or to aid comprehension.

In connection with the following figures, embodiments of an optoelectronic semiconductor device 100 and components thereof are described. The optoelectronic semiconductor device 100 has an optoelectronic semiconductor chip 10 in a housing 20. In the following embodiments, the optoelectronic semiconductor device 100 is embodied purely by way of example as a light-emitting semiconductor device with a semiconductor laser diode as the optoelectronic semiconductor chip 10. Alternatively, other semiconductor chip embodiments are possible, such as a superluminescent diode (SLED), a light emitting diode (LED), a photodiode, or another optoelectronic semiconductor chip. Further, it is also possible for the optoelectronic semiconductor device 100 to comprise a plurality of the same or different optoelectronic semiconductor chips 10 and/or other electronic components in the housing 20.

Particularly preferably, the housing 20 has dimensions that are less than or equal to 5 cm or less than or equal to 2 cm or less than or equal to 1 cm or less than or equal to 0.5 cm or less than or equal to 0.3 cm. In other words, the optoelectronic semiconductor device 100 is preferably formed as a so-called semiconductor housing.

The at least one optoelectronic semiconductor chip 10, i.e. in the embodiments shown in particular the at least one semiconductor laser diode, can have at least one active layer which is configured and intended to generate light in an active region during operation. In particular, the active layer can be part of a semiconductor layer sequence with a plurality of semiconductor layers and have a main extension plane that is perpendicular to an arrangement direction of the layers of the semiconductor layer sequence. For example, the active layer can have exactly one active region. Furthermore, the semiconductor laser diode can also have a plurality of active regions in an active layer and/or a plurality of active layers that can be stacked on top of each other within the semiconductor layer sequence and connected in series with each other, for example, via tunnel junctions. The semiconductor layer sequence can be configured in particular as an epitaxial layer sequence, i.e. as an epitaxially grown semiconductor layer sequence. For example, the semiconductor layer sequence can be based on InAlGaN. InAlGaN-based semiconductor layer sequences include in particular those in which the epitaxially grown semiconductor layer sequence generally has a layer sequence of different individual layers, which contains at least one individual layer that has a material from the III V-compound semiconductor material system InₓAl_{y}Ga_{1-x-y}N with 0≤x 1, 0≤y≤1 and x+y≤1. In particular, the active layer can be based on such a material. Semiconductor layer sequences having at least one active layer based on InAlGaN can, for example, preferentially emit electromagnetic radiation in an ultraviolet to green wavelength range.

Alternatively or additionally, the semiconductor layer sequence can also be based on InAlGaP, i.e., the semiconductor layer sequence can have different individual layers, of which at least one individual layer, for example the active layer, has a material from the III-V compound semiconductor material system InₓAl_{y}Ga_{1-x-y}P with 0≤x≤1, 0≤y≤1 and x+y≤1. Semiconductor layer sequences having at least one active layer based on InAlGaP, for example, can preferentially emit electromagnetic radiation with one or more spectral components in a green to red wavelength range.

Alternatively or additionally, the semiconductor layer sequence can comprise other III-V compound semiconductor material systems, for example an InAlGaAs-based material, or II-VI-compound semiconductor material systems. In particular, an active layer comprising an InAlGaAs-based material can be capable of emitting electromagnetic radiation having one or more spectral components in a red to infrared wavelength range. A II-VI compound semiconductor material can include at least one element from the second main group, such as Be, Mg, Ca, Sr, and one element from the sixth main group, such as O, S, Se. For example, II-VI compound semiconductor materials include ZnSe, ZnTe, ZnO, ZnMgO, CdS, ZnCdS, and MgBeO.

The active layer and in particular the semiconductor layer sequence with the active layer can be deposited on a substrate. For example, the substrate can be formed as a growth substrate on which the semiconductor layer sequence is grown. The active layer and, in particular, the semiconductor layer sequence with the active layer can be produced by means of an epitaxy process, for example by means of metal organic vapor phase epitaxy (MOVPE) or molecular beam epitaxy (MBE). In particular, this can mean that the semiconductor layer sequence is grown on the growth substrate. Furthermore, the semiconductor layer sequence can be provided with electrical contacts in the form of one or more contact elements. Furthermore, it can also be possible that the growth substrate is removed after the growth process. In this case, the semiconductor layer sequence can, for example, also be transferred to a substrate formed as a carrier substrate after the growth process. The substrate can comprise a semiconductor material, for example a compound semiconductor material system mentioned above, or another material. In particular, the substrate can comprise or be made of sapphire, GaAs, GaP, GaN, InP, SiC, Si, Ge, and/or a ceramic material such as SiN or AlN.

For example, the active layer can have a conventional pn junction, a double heterostructure, a single quantum well (SQW) structure, or a multiple quantum well (MQW) structure for light generation. In addition to the active layer, the semiconductor layer sequence can include additional functional layers and functional regions, such as p- or n-doped charge carrier transport layers, i.e., electron or hole transport layers, undoped or p- or n-doped confinement, cladding or waveguide layers, barrier layers, planarization layers, buffer layers, protective layers and/or electrode layers, and combinations thereof. Furthermore, additional layers, such as buffer layers, barrier layers and/or protective layers can also be arranged perpendicular to the growth direction of the semiconductor layer sequence, for example around the semiconductor layer sequence, i.e. for example on the side surfaces of the semiconductor layer sequence.

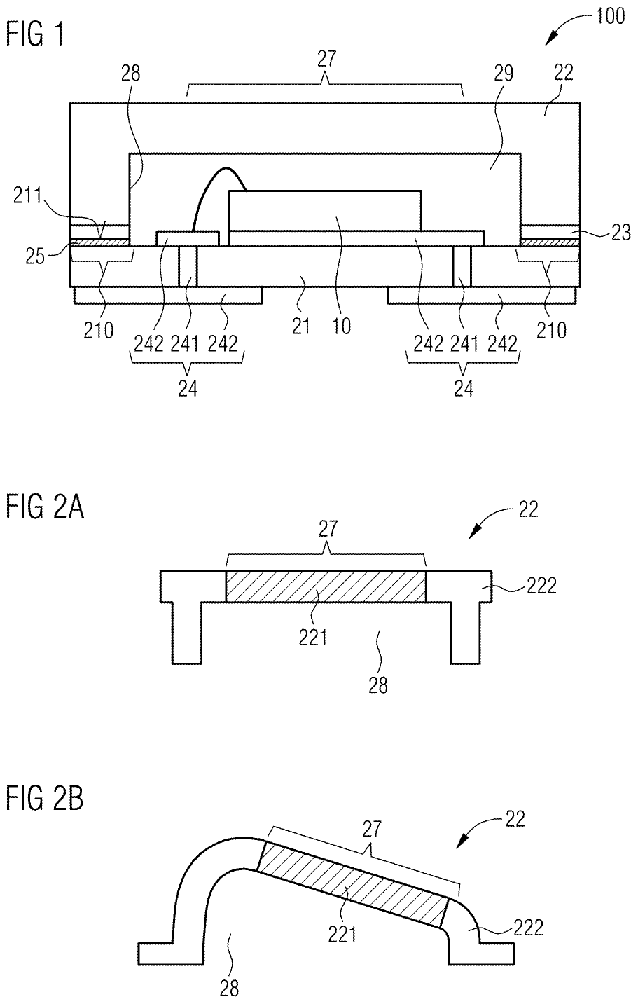

The optoelectronic semiconductor chip 10 can, for example, be formed as an edge-emitting semiconductor laser diode in which the light generated in the at least one active layer during operation is emitted via a side surface formed as a facet, which can be formed perpendicular to the at least one active layer. Alternatively, the semiconductor laser diode can also be configured, for example, as a vertically emitting laser diode such as a VCSEL diode (VCSEL: “vertical-cavity surface-emitting laser”), in which the light generated in the at least one active layer during operation is emitted via a surface of the semiconductor layer sequence arranged parallel to the active layer. Furthermore, a vertically emitting semiconductor laser diode in the form of an edge-emitting semiconductor laser diode with integrated deflection optics is also possible, for example. FIG. 1 shows an embodiment in which the optoelectronic semiconductor chip 10 is configured as a vertically emitting semiconductor laser diode, i.e. in the figure shown as an upward emitting semiconductor laser diode.

As shown in FIG. 1, the housing 20 has a base part 21 and a cover part 22. Between the base part 21 and the cover part 22 a connecting layer 23 is arranged, by means of which the cover part 22 is mounted and thus fastened to the base part 21. An interior space 29 of the housing 20 is enclosed by the base part 21 and the cover part 22 and the connecting layer 23. In particular, at least one or both of the base part 21 and the cover part 22 can have a recess 28 through which the interior space 29 is formed when the base part 21 and the cover part 22 are joined together and mounted to each other by means of the connecting layer 23. Particularly preferably, the interior space 29 is hermetically sealed by the base part 21, the cover part 22 and the connecting layer 23.

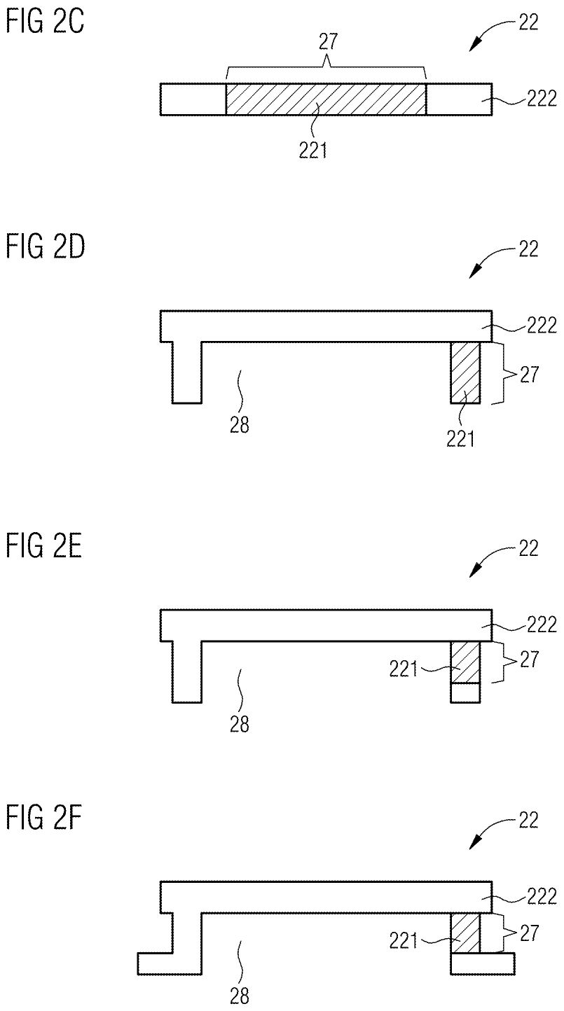

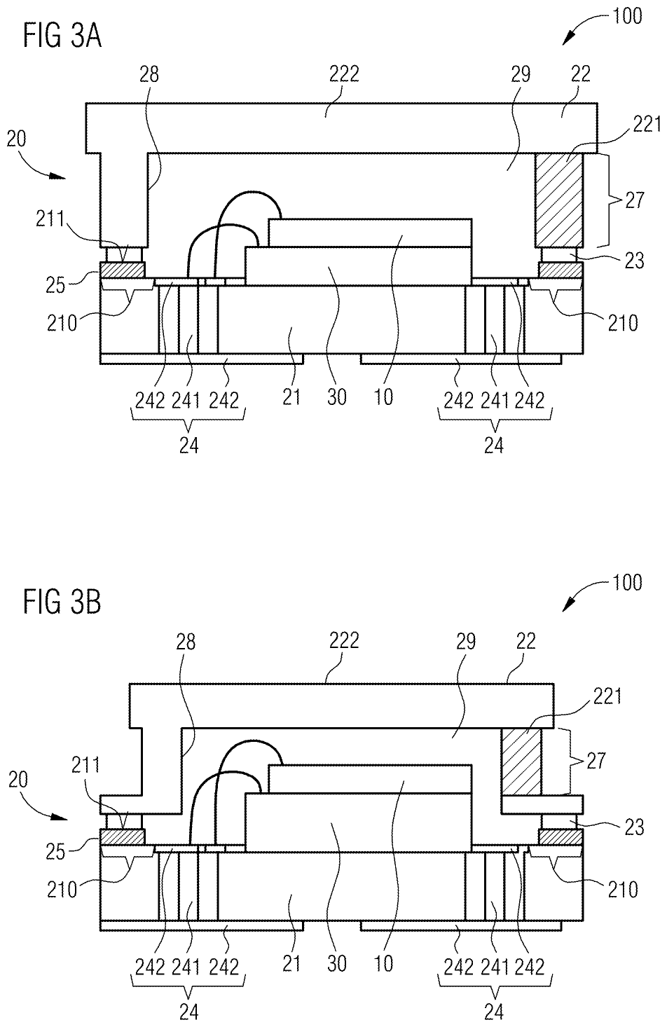

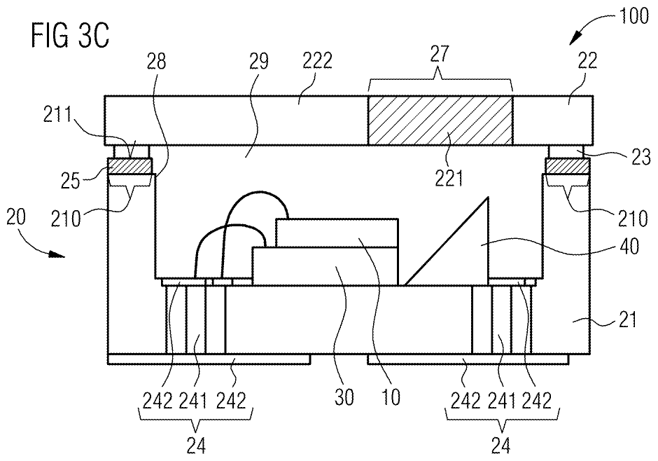

In the embodiment shown in FIG. 1 as well as in the embodiments shown in FIGS. 2A, 2B, 2D to 2F, 3A and 3B, the cover part 22 has a recess 28, while in the embodiment shown in FIG. 3C, a base part 21 is shown with a recess 28.

The at least one optoelectronic semiconductor chip 10 is mounted on the base part 21 in the interior space 29 and is preferably electrically connected. The direction of arrangement of the at least one optoelectronic semiconductor chip 10 on the base part 21 corresponds to a vertical direction. Directions perpendicular to the vertical direction, which are directed parallel to a main extension plane of the base part 21 and in particular a mounting surface of the base part 21, are referred to as lateral directions.

The base part 21 is configured as a ceramic carrier and thus has a ceramic material, for example with or made of aluminum nitride, as the main component. The ceramic carrier can preferably be a single-layer ceramic carrier or a multilayer ceramic carrier. A single-layer ceramic carrier can be plate-shaped, for example, as shown in FIGS. 1, 3A and 3B, and thus form a base plate.

A multilayer ceramic carrier, as exemplarily shown in FIG. 3C, can be formed of at least two or more layers of the same ceramic material or of different ceramic materials, which are deposited and sintered on each other to form the base part 21. In the example embodiment shown in FIG. 3C, one of the layers forms a base plate on which the at least one optoelectronic semiconductor chip 10 is mounted, while at least one other layer is frame-shaped and laterally surrounds the at least one optoelectronic semiconductor chip 10, thereby forming the recess 28 in which the at least one optoelectronic semiconductor chip 10 is arranged.

Particularly preferably, the housing 10 can be surface-mountable. The optoelectronic semiconductor component 100 can thus particularly preferably be a surface-mountable component, i.e. a so-called SMD component (SMD: “surface-mounted device”), which can be mounted on a carrier such as a printed circuit board by soldering. Accordingly, the ceramic carrier can be surface-mountable in a particularly preferred manner.

For electrical contacting of the components arranged in the housing 20, such as in particular the at least one optoelectronic semiconductor chip 10, the housing 20, particularly preferably the base part 21, has at least one electrical contact element 24. The at least one electrical contact element can, for example, have or be formed by one or more conductor tracks, one or more electrical feedthroughs (“vias”), one or more leadframes or leadframe parts, one or more electrode surfaces and combinations thereof on one or more surfaces of the base part and/or embedded in the base part. In particular, the housing 20 can include a plurality of electrical contact elements 24. For example, as contact elements 24, as shown in FIGS. 1 and 3A to 3C, the base part 21 can have at least two vias 241 each connecting an electrode surface 242 in the interior space to an electrode surface 242 on an outer surface of the base part 21 facing away from the interior space. The optoelectronic semiconductor chip 10 can be directly mounted on one electrode surface 242, as indicated in FIG. 1, while the other side of the optoelectronic semiconductor chip 10 can be connected via a bonding wire. Further, the optoelectronic semiconductor chip 10 can be mounted on a heat sink 30 and electrically connected via suitable bonding wire connections, as shown in FIGS. 3A to 3C. In addition, other electrical connection methods are also possible. Furthermore, depending on the design of the optoelectronic semiconductor chip 10 and/or in the case of an optoelectronic semiconductor device having more than one optoelectronic semiconductor chip 10, more than two contact elements 24 are possible.

In the embodiment described in connection with FIG. 1 of an optoelectronic semiconductor device configured as a light-emitting semiconductor device with a vertically emitting laser diode as optoelectronic semiconductor chip 10, the cover part 22 is configured to be transmissive to light, in particular to the light generated by the optoelectronic semiconductor chip 10, at least in a region 27 above the optoelectronic semiconductor chip 10. Furthermore, the entire cover part 22 can be transmissive to light. Particularly preferably, the cover part 22 can be clearly translucent at least in the region 27 provided for light transmission and thus as transparent as possible. Alternatively or additionally, the cover part 22 can have an optical property at least in the region 27 provided for light transmission and can be, for example, light-diffusing or light-refracting. For example, the region 27 can be configured as a lens.

The cover part 22 is formed of one or more glass materials. For example, the cover part can be formed of a glass material such as borosilicate glass.

The connecting layer 23 has a glass solder and is particularly preferably made of a glass solder. By means of a glass solder, it is possible to compensate for unevenness and other irregularities in an order of magnitude of up to 20 μm or even more on the joining surfaces adjacent to the joining layer 23. The connecting layer 23 formed by the glass solder for mounting the cover part 22 on the base part 21 is directly adjacent to the cover part 22 and is thus in direct contact with the cover part 22. An adhesion-promoting layer, such as metallization, as would be necessary in the case of a solder joint, is not necessary on the cover part 22. The connecting layer can, for example, be applied to the base part 21 or to the cover part 22 before assembly. A permanent and preferably hermetically sealed connection of base part 21 and cover part 22 can be achieved by the action of heat and/or by laser irradiation.

The base part 21, i.e. in particular the ceramic carrier of the base part 21, has a connecting region 210. The connecting region 210 is in particular the region of the ceramic carrier to which the connection layer 23 is applied. Particularly preferably, the base part 21 has a nickel-containing surface 211 in the connecting region 210, which is in direct contact with the connecting layer 23, that is in particular the glass solder. By means of a nickel-containing surface 211, a particularly good adhesion of the glass solder can be achieved. For example, the nickel-containing surface 211 can be formed by a nickel-containing layer 25. Particularly preferably, the nickel-containing layer 25 can have a relative amount of greater than or equal to 95 vol % nickel based on a total volume of the nickel-containing layer. The nickel-containing layer 25 can, for example, be vapor-deposited onto the base part 21, in particular the ceramic carrier, or sintered with the ceramic material of the ceramic carrier as part of the manufacturing process of the ceramic carrier.

Preferably, the base part 21 and the cover part 22 have materials with similar coefficients of thermal expansion. This allows stresses between the base part 21 and the cover part 22, which could be caused by different thermal expansion coefficients during temperature changes, to be minimized.

For example, the cover part 22 can be fabricated by a wafer-based process in the form of a composite of a plurality of interconnected cover parts, the composite being divided into individual cover parts after fabrication. For this purpose, for example, a silicon wafer can be provided to form a negative mold of the composite of cover parts. The glass material for the cover parts 22 can be a material having a softening temperature lower than the softening temperature of the negative mold. The glass material can be bonded to the negative mold in the form of a glass wafer, for example. Structures and depressions can be provided in the negative mold, for example by etching, which later correspond to three-dimensionally formed regions in the cover parts 22. Three-dimensional forming of the cover part composite can be achieved by the action of temperature and pressure.

For example, the cover part 22 shown in FIG. 1 can be formed entirely of a same glass material. FIGS. 2A to 3C show embodiments of the cover part 22 having an optical window 221 in a frame part 222. In particular, the term optical window 221 refers to a portion of the cover part 22 that has sufficient optical quality for the intended application of the optoelectronic semiconductor device 100. For example, in composite-based fabrication, prefabricated optical windows can be placed in the negative mold and formed with a frame material to form the frame parts 222 under the action of heat and/or pressure. In this regard, a glass material having a lower softening point than the negative mold can be used for the frame parts 222, while a glass material having a higher softening point than the glass material for the frame parts 222 can be used for the optical windows 221.

In each of FIGS. 2A and 2B, a cover part 22 is shown with a recess 28 having an optical window 221 arranged in the optoelectronic semiconductor device above the optoelectronic semiconductor chip. As indicated in FIG. 2B, the manufacturing method described above allows arbitrary shapes of the cover part 22. In FIG. 2C, a cover part 22 is shown which has no recess compared to the embodiments of FIGS. 2A and 2B and is plate-shaped.

As indicated in FIGS. 2D to 2F, the optical window 221 can also be arranged laterally, that is, on the side with respect to the at least one optoelectronic semiconductor chip in the optoelectronic semiconductor device. Here, as indicated in FIG. 2D, the optical window 221 can form a portion of a sidewall of the cover part 22 that is adjacent to the connecting layer in the optoelectronic semiconductor device. Further, the optical window 221 can also be integrated in a frame-shaped side wall, as indicated in FIGS. 2E and 2F, wherein, as indicated in FIG. 2F, flanks for connection to the connecting layer can be provided in the connecting region of the cover part 22.

FIGS. 3A and 3B show optoelectronic semiconductor devices 100 formed as side emitters having edge-emitting laser diodes as at least one optoelectronic semiconductor chip 10. Purely by way of example, the optoelectronic semiconductor devices 100 of FIGS. 3A and 3B have the cover parts 22 according to the embodiments of FIGS. 2D and 2F.

In FIG. 3C, an optoelectronic semiconductor device 100 configured as a vertical emitter is shown, which purely as an example comprises the cover part 22 according to the embodiment of FIG. 2C. The at least one optoelectronic semiconductor chip 10 is formed as an edge-emitting semiconductor laser diode as in the two previous embodiments. In order to redirect the light emitted in a lateral direction to the vertical direction, the optoelectronic semiconductor device 100 in the shown embodiment has a redirecting element 40, for example in the form of a prism, mounted on the base part 21.

The described optoelectronic semiconductor devices 100 can be characterized by low cost, low tolerance requirements for the components to be interconnected, low heat input during the fabrication process, known and volume-proven sub-processes, and good thermal conductivity, particularly due to the use of AlN ceramics.

The features and embodiments described in connection with the figures can be combined with each other according to further embodiments, even if not all combinations are explicitly described. Furthermore, the embodiments described in connection with the figures can alternatively or additionally have further features according to the description in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

1. An optoelectronic semiconductor device comprising at least one optoelectronic semiconductor chip in an interior space of a housing, wherein
the housing has a base part and a cover part,
the base part is configured as a ceramic carrier,
the cover part is formed of one or more glass materials,
a connecting layer of a glass solder is arranged between the base part and the cover part, and
the ceramic carrier has a connecting region with a nickel-containing surface that is in direct contact with the glass solder.

2. The optoelectronic semiconductor device according to claim 1, wherein the base part has a recess in which the optoelectronic semiconductor chip is arranged.

3. The optoelectronic semiconductor device according to claim 2, wherein the base part is formed as a multilayer ceramic carrier.

4. The optoelectronic semiconductor device according to claim 1, wherein the cover part has a recess in which the optoelectronic semiconductor chip is arranged.

5. The optoelectronic semiconductor device according to claim 1, wherein the cover part is fully translucent.

6. The optoelectronic semiconductor device according to claim 1, wherein the cover part includes an optical window arranged in a frame part.

7. The optoelectronic semiconductor device according to claim 6, wherein the optical window comprises a first glass material and the frame part comprises a second glass material different from the first glass material.

8. The optoelectronic semiconductor device according to claim 6, wherein the optical window is arranged adjacent to the optoelectronic semiconductor chip in a lateral direction.

9. The optoelectronic semiconductor device according to claim 6, wherein the optical window is arranged in a vertical direction above the optoelectronic semiconductor chip.

10. The optoelectronic semiconductor device according to claim 1, wherein the cover part comprises at least a portion made of a glass material having a softening point lower than silicon.

11. The optoelectronic semiconductor device according to claim 1, wherein the nickel-containing surface is formed by a nickel-containing layer.

12. The optoelectronic semiconductor device according to claim 11, wherein the nickel-containing layer has a relative amount of greater than or equal to 95 vol % nickel based on a total volume of the nickel-containing layer.

13. The optoelectronic semiconductor device according to claim 1, wherein the connection layer is in direct contact with the cover part.

14. The optoelectronic semiconductor device according to claim 1, wherein the interior space is hermetically sealed by the base part, the connecting layer and the cover part.

15. The optoelectronic semiconductor device according to claim 1, wherein the optoelectronic semiconductor chip is a semiconductor laser diode.
